(19) United States
(12) Patent Application Publication
(10) Pub. No.: US 2024/0289511 A1
(43) Pub. Date: Aug. 29, 2024

(54) METHOD OF DESIGNING A METASURFACE, A BEAM SHAPER, A DEVICE AND ELECTRONIC EQUIPMENT

(71) Applicant: SHENZHEN METALENX TECHNOLOGY CO.,LTD, Shenzhen (CN)

(72) Inventors: Jianfa CHEN, Shenzhen (CN); Chenglong HAO, Shenzhen (CN); Fengze TAN, Shenzhen (CN); Jian ZHU, Shenzhen (CN)

(73) Assignee: SHENZHEN METALENX TECHNOLOGY CO.,LTD, Shenzhen (CN)

(21) Appl. No.: 18/420,726

(22) Filed: Jan. 23, 2024

(30) Foreign Application Priority Data
Feb. 24, 2023 (CN) 202310196037.5

(51) Int. Cl. G06F 30/17; G02B 27/09

(52) U.S. Cl. CPC G06F 30/17; G02B 27/0944

(57) ABSTRACT

A method of designing a metasurface, a beam shaper, a device and electronic equipment are provided. The method of designing the metasurface includes: determining a type of an incident beam and parameters of the incident beam; determining a type of an outgoing beam and a parameter of the outgoing beam; based on the parameters of the incident beam and the parameter of the outgoing beam, determining an initial value of a diffraction phase distribution; the diffraction phase distribution represents a phase distribution configured to modulate the incident beam to the outgoing beam; based on the type of the incident beam and the type of the outgoing beam, iteratively optimizing the diffraction phase distribution to obtain an optimized diffraction phase distribution; generating a target phase distribution according to the optimized diffraction phase distribution; and generating the metasurface according to the target phase distribution.

### CROSS-REFERENCE TO RELATED APPLICATION

This application claims the benefit of priority from Chinese Patent Application No. 202310196037.5, filed on Feb. 24, 2023. The content of the aforementioned application, including any intervening amendments thereto, is incorporated herein by reference in its entirety.

### TECHNICAL FIELD

The present disclosure relates to the field of beam shaping, in particular to a method of designing a metasurface, a beam shaper, a device and electronic equipment.

### BACKGROUND

Traditional beam shapers generally use a set of lenses including multiple spherical lenses and/or aspherical lenses. However, the fabrication of the spherical lenses and the aspherical lenses is difficult in actual processing. In addition, a long spatial distance is required to achieve the assembly of these traditional lenses, causing the beam shapers to be bulky and thus occupy a lot of space. Therefore, it is particularly important to design a beam shaper that is miniaturized and easy to be processed, as well as having good shaping performances.

### SUMMARY

In view of the above technical problems, a method of designing a metasurface, a beam shaper, a device and electronic equipment are provided according to embodiments of the present disclosure.

In a first aspect of the present disclosure, a method of designing a metasurface is provided. The method includes: determining a type of an incident beam and parameters of the incident beam; where the parameters of the incident beam include a wavelength of the incident beam and a light intensity distribution of the incident beam; determining a type of an outgoing beam and a parameter of the outgoing beam; where the parameter of the outgoing beam includes a light intensity distribution of the outgoing beam; based on the parameters of the incident beam and the parameter of the outgoing beam, determining an initial value of a diffraction phase distribution; the diffraction phase distribution represents a phase distribution configured to modulate the incident beam to the outgoing beam; based on the type of the incident beam and the type of the outgoing beam, iteratively optimizing the diffraction phase distribution to obtain an optimized diffraction phase distribution; generating a target phase distribution according to the optimized diffraction phase distribution; and generating the metasurface according to the target phase distribution.

In an embodiment, a step of determining the initial value of the diffraction phase distribution based on the parameters of the incident beam and the parameter of the outgoing beam includes: determining a two-dimensional phase distribution; where the two-dimensional phase distribution represents a phase distribution configured to modulate the incident beam directed towards the metasurface which is of a plane defined by a first direction and a second direction; the first direction represents a direction that is coplanar with the metasurface to be designed; and the first direction and the second direction are perpendicular to each other; taking the two-dimensional phase distribution as the initial value of the diffraction phase distribution.

In an embodiment, a step of determining the two-dimensional phase distribution includes: redistributing the light intensity distribution of the incident beam into the light intensity distribution of the outgoing beam to obtain a one-dimensional phase distribution; the one-dimensional phase distribution represents a phase distribution that modulates the incident beam directed in the first direction; determining the two-dimensional phase distribution according to a type of the light intensity distribution of the outgoing beam and the one-dimensional phase distribution.

In an embodiment, the incident beam is a Gaussian beam; and the outgoing beam is a flat-top beam.

In an embodiment, the type of the light intensity distribution of the outgoing beam is of a rotationally symmetrical shape.

In an embodiment, the type of the light intensity distribution of the outgoing beam is of a cylinder; and a step of determining the two-dimensional phase distribution according to the type of the light intensity distribution of the outgoing beam and the one-dimensional phase distribution includes: performing a rotational symmetry to the one-dimensional phase distribution to obtain the two-dimensional phase distribution.

In an embodiment, the type of the light intensity distribution of the outgoing beam is out of a rotationally symmetrical shape.

In an embodiment, the type of the light intensity distribution of the outgoing beam is of a cuboid; and a step of determining the two-dimensional phase distribution according to the type of the light intensity distribution of the outgoing beam and the one-dimensional phase distribution includes: determining a phase distribution configured to modulate the incident beam directed in the second direction; superimposing the phase distribution configured to modulate the incident beam directed in the second direction and the one-dimensional phase distribution to obtain the two-dimensional phase distribution.

In an embodiment, the one-dimensional phase distribution satisfies:

$${φ}_{1} ( x ) = \frac{2 π}{λ z} {\int }_{0}^{x} [ u ( t ) - t ] dt ;$$

the two-dimensional phase distribution satisfies:

$${φ}_{2} ( x , y ) = {φ}_{1} ( \sqrt{{x}^{2} + {y}^{2}} ) ;$$

where, φ₁(x) represents the one-dimensional phase distribution; x represents a position on the metasurface in the first direction; λ represents the wavelength of the incident beam; z represents a distance that the outgoing beam travels to a diffraction plane; u(t) represents a conversion relationship between a position u of the light intensity distribution of the outgoing beam and a position t of the incident beam in the first direction, and t represents an integral variable; φ₂(x, y) represents the two-dimensional phase distribution; y represents a position on the metasurface in the second direction.

In an embodiment, the two-dimensional phase distribution satisfies:

$${φ}_{2} ( x , y ) = {φ}_{1 x} ( x ) + {φ}_{1 y} ( y ) ;$$

and

$${φ}_{1 x} ( x ) = \frac{2 π}{λ z} {\int }_{0}^{x} [ {u}_{x} ( t ) - t ] dt ; {φ}_{1 y} ( y ) = \frac{2 π}{λ z} {\int }_{0}^{y} [ {u}_{y} ( t ) - t ] dt ;$$

where, φ₂(x, y) represents the two-dimensional phase distribution; A represents the wavelength of the incident beam; z represents a distance that the outgoing beam travels to a diffraction plane; t represents an integral variable; φ₁ₓ(x) represents a one-dimensional phase distribution in the first direction; x represents a position on the metasurface in the first direction; uₓ(t) represents a conversion relationship between a position uₓ of the light intensity distribution of the outgoing beam in the first direction x and a position t of the incident beam in the first direction x; φ_{1y}(y) represents a one-dimensional phase distribution in the second direction; y represents a position on the metasurface in the second direction; u_{y}(t) represents a conversion relationship between a position u_{y} of the light intensity distribution of the outgoing beam in the second direction y and a position t of the incident beam in the second direction y.

In an embodiment, a step of iteratively optimizing the diffraction phase distribution based on the type of the incident beam and the type of the outgoing beam to obtain the optimized diffraction phase distribution includes: determining a first light source function of the incident beam according to the type of the incident beam; and determining a second light source function of the outgoing beam according to the type of the outgoing beam; plugging the initial value of the diffraction phase distribution into a phase recovery algorithm, and performing an optimization based on the first light source function and the second light source function to obtain the optimized diffraction phase distribution.

In an embodiment, a step of generating the target phase distribution according to the optimized diffraction phase distribution includes: taking the optimized diffraction phase distribution as the target phase distribution.

In an embodiment, a step of generating the target phase distribution according to the optimized diffraction phase distribution includes: superimposing an additional phase distribution on the optimized diffraction phase distribution to obtain the target phase distribution. The additional phase distribution represents a phase distribution configured for collimating the incident beam or configured for focusing the outgoing beam.

In an embodiment, the additional phase distribution satisfies:

$${φ}_{3} ( x , y ) = - \frac{2 π}{λ} ( \sqrt{{x}^{2} + {y}^{2} + {f}^{2}} - f ) ;$$

where, φ₃(x, y) represents an additional phase distribution of the metasurface to be designed at a position (x, y); 1 represents the wavelength of the incident beam; f represents a focal length of the metasurface to be designed.

In a second aspect of the present disclosure, a beam shaper is provided. The beam shaper includes a metasurface designed by the method of designing the metasurface according to any of the above embodiments.

In a third aspect of the present disclosure, a device of designing a metasurface is provided. The device includes a first determination module, a second determination module, a generation module and an optimization module. The first determination module is configured to determine a type of an incident beam and parameters of the incident beam; the parameters of the incident beam include a wavelength of the incident beam and a light intensity distribution of the incident beam. The second determination module is configured to determine a type of an outgoing beam and a parameter of the outgoing beam; the parameter of the outgoing beam includes a light intensity distribution of the outgoing beam. The generation module is configured to determine an initial value of a diffraction phase distribution based on the parameters of the incident beam and the parameter of the outgoing beam; the diffraction phase distribution represents a phase distribution configured to modulate the incident beam to the outgoing beam. The optimization module is configured to iteratively optimize the diffraction phase distribution based on the type of the incident beam and the type of the outgoing beam to obtain an optimized diffraction phase distribution; and the optimization module is also configured to generate a target phase distribution according to the optimized diffraction phase distribution and generate the metasurface according to the target phase distribution.

In a fourth aspect of the present disclosure, electronic equipment is provided. The electronic equipment includes a processor and a memory. The memory includes a computer program stored in the memory. The processor is configured to execute the computer program stored in the memory, so as to implement the method of designing the metasurface of the first aspect of the present disclosure.

In a fifth aspect of the present disclosure, a non-transitory computer-readable storage medium in which a computer program is stored. The computer program is executed by a processor, so as to implement the method of designing the metasurface of the first aspect of the present disclosure.

In a sixth aspect, a computer program product is provided. The computer program product includes a computer program. The computer program is executed to implement the method of designing the metasurface of any one of feasible designs of the first aspect of the present disclosure.

The method of designing the metasurface, the beam shaper, the device and the electronic equipment as provided in the present disclosure are provided. In the method of designing the metasurface, an initial value of the diffraction phase distribution is firstly obtained by calculation and then the diffraction phase distribution is optimized (by starting from the initial value) to obtain an optimized diffraction phase distribution. Based on the optimized diffraction phase distribution, a target phase distribution for generating the metasurface to be designed is finally acquired. Instead of directly taking the diffraction phase distribution obtained based on a light intensity redistribution principle as the target phase distribution to generate the metasurface, the method disclosed herein takes the diffraction phase distribution as the initial value in optimization by simulation, which overcomes the problems in the existing technical solutions, for example, edges of the light intensity distribution of the outgoing beam are too smooth because the existing technical solutions solely use the light intensity redistribution principle to calculate the diffraction phase distribution. For another example, a simulation by using randomly generated initial values easily leads to falling into local optimum, causing the shaped outgoing beam to be poor in uniformity and have a light intensity distribution with a rough surface. Thus, a metasurface designed in the present disclosure is more applicable to the beam shaper due to its advantages of being miniaturized and having lower fabrication difficulties and better shaping performances.

### BRIEF DESCRIPTION OF THE DRAWINGS

In order to explain embodiments of the present disclosure or the prior art more clearly, drawings used in the description of the embodiments or the prior art will be briefly explained below.

FIG. 1 shows a flow chart of a method of designing a metasurface according to an embodiment of the present disclosure;

FIG. 2 shows a schematic diagram of shaping a Gaussian beam into a flat-top beam in a method of designing a metasurface according to an embodiment of the present disclosure;

FIG. 3 shows a principle diagram of beam shaping in a method of designing a metasurface according to an embodiment of the present disclosure;

FIG. 4 shows a flow chart of a step of “determining an initial value of a diffraction phase distribution based on parameters of an incident beam and a parameter of an outgoing beam” in a method of designing a metasurface according to an embodiment of the present disclosure;

FIG. 5 shows a flow chart of a step of “iteratively optimizing the diffraction phase distribution based on a type of the incident beam and a type of the outgoing beam” in a method of designing a metasurface according to an embodiment of the present disclosure;

FIG. 6 is a principle diagram showing an application scenario of collimation in a method of designing a metasurface according to an embodiment of the present disclosure;

FIG. 7 shows a principle diagram showing an application scenario of focusing in a method of designing a metasurface according to an embodiment of the present disclosure;

FIG. 8 shows a schematic diagram of a light intensity distribution of a Gaussian beam projected on a surface of a beam shaper according to Embodiment 1 of the present disclosure;

FIG. 9 shows a schematic diagram of a cross-sectional distribution of the Gaussian beam at y=0 according to Embodiment 1 of the present disclosure;

FIG. 10 shows a schematic diagram of a light intensity distribution of a flat-top beam projected on a diffraction plane according to Embodiment 1 of the present disclosure;

FIG. 11 shows a schematic diagram of a cross-sectional distribution of the flat-top beam at y=0 according to Embodiment 1 of the present disclosure;

FIG. 12 shows a schematic diagram of a phase distribution of the beam shaper according to Embodiment 1 of the present disclosure;

FIG. 13 shows a schematic diagram of a cross-sectional distribution of the phase distribution of the beam shaper at y=0 according to Embodiment 1 of the present disclosure;

FIG. 14 is a schematic diagram showing a nanostructure according to Embodiment 1 of the present disclosure;

FIG. 15 shows a schematic diagram showing a relationship between a diameter D of the nanostructure and a phase of the nanostructure according to Embodiment 1 of the present disclosure;

FIG. 16 shows a schematic diagram of a light intensity distribution of a Gaussian beam projected on a surface of a beam shaper according to Embodiment 2 of the present disclosure;

FIG. 17 shows a schematic diagram of a light intensity distribution of a flat-top beam projected on a diffraction plane according to Embodiment 2 of the present disclosure;

FIG. 18 shows a schematic diagram of a cross-sectional distribution of the flat-top beam at y=0 according to Embodiment 2 of the present disclosure;

FIG. 19 shows a schematic diagram of a phase distribution of the beam shaper according to Embodiment 2 of the present disclosure;

FIG. 20 shows a schematic diagram of a light intensity distribution of a Gaussian beam according to Embodiment 3 of the present disclosure;

FIG. 21 shows a schematic diagram of a light intensity distribution of a flat-top beam according to Embodiment 3 of the present disclosure;

FIG. 22 shows a schematic diagram of a cross-sectional distribution of the flat-top beam at y=0 according to Embodiment 3 of the present disclosure;

FIG. 23 shows a schematic diagram of a phase distribution of a beam shaper according to Embodiment 3 of the present disclosure;

FIG. 24 schematically shows a structural diagram of a device of designing a metasurface according to an embodiment of the present disclosure; and

FIG. 25 schematically shows a structural diagram of electronic equipment according to an embodiment of the present disclosure.

### DETAILED DESCRIPTION OF DISCLOSED EMBODIMENTS

Embodiments of the present disclosure will be described below with reference to the accompanying drawings of the present disclosure.

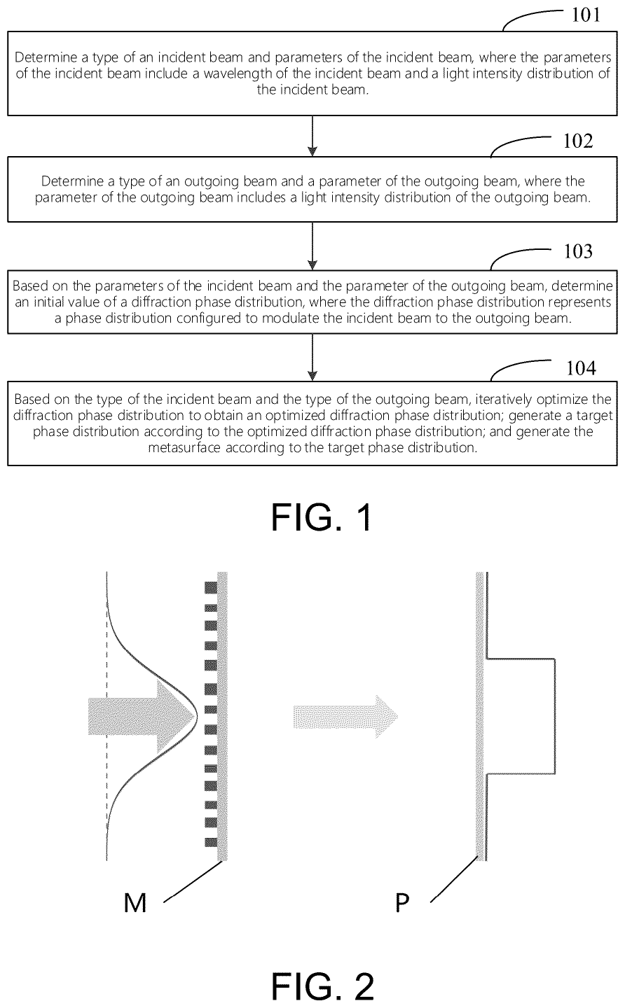

FIG. 1 shows a flow chart of a method of designing a metasurface according to an embodiment of the present disclosure. As shown in FIG. 1, the method includes the following steps 101-104.

Step 101: determining a type of an incident beam and parameters of the incident beam. The parameters of the incident beam include a wavelength of the incident beam and a light intensity distribution of the incident beam.

Step 102: determining a type of an outgoing beam and a parameter of the outgoing beam. The parameter of the outgoing beam includes a light intensity distribution of the outgoing beam.

In the present disclosure, the incident beam is a beam to be shaped and is intended to propagate towards the metasurface to be designed. The outgoing beam is a beam after shaping, i.e., a beam that exits from the metasurface to be designed. Where, the type of the incident beam and the type of the outgoing beam are not limited thereto. In other words, the incident beam may be any type of beam that needs to be shaped, and the outgoing beam may be any type of beam that is determined based on actual needs.

Optionally, as shown in FIG. 2, the incident beam is a Gaussian beam; and the outgoing beam is a flat-top beam.

In other words, a metasurface (indicated by a reference symbol M of FIG. 2) designed in the present embodiment modulates a Gaussian beam (which is represented by a curve on a left side of the metasurface M of FIG. 2) injected on the metasurface into a flat-top beam (which is represented by a raised line on a right side of the metasurface M of FIG. 2). The metasurface designed in the present embodiment also directs the flat-top beam obtained after shaping to a diffraction plane (indicated by a reference symbol P of FIG. 2), and a direction pointed by two arrows of FIG. 2 is a direction along which the Gaussian beam propagates. The following is the reason why the present embodiment selects a Gaussian beam as the incident beam and selects a flat-top beam as the outgoing beam. Usually, a beam emitted from a laser source is a Gaussian beam. For example, all of a solid laser source, a gas laser source and a fiber laser source emit light which has a Gaussian distribution at any cross-section of the beam. However, in fields such as laser material processing and laser medical treatment, a rough cross-section is made by cutting across a material by a Gaussian distributed laser source (i.e., a Gaussian beam), which is detrimental to the subsequent processing. In addition, in fields such as image display and lighting, Gaussian spots (i.e., Gaussian distributed spots) having uneven sectional light intensity distribution seriously affect the quality of color rendering. Therefore, it is necessary to modulate the Gaussian beam emitted from the laser source into a type of beam that has the uniform light intensity distribution, such as a flat-top beam. It should be noted that shaping the most common Gaussian beam into a flat-top beam is only an example of the present embodiment, which does not mean that the method of designing the metasurface provided in the present disclosure is only applicable to the foregoing example.

Where, after the type of the incident beam is determined, the parameters of the incident beam may be determined based on the type of the incident beam. The parameters of the incident beam include a wavelength of the incident beam and a light intensity distribution of the incident beam. Where, the light intensity distribution of the incident beam reflects a state of a light spot formed by projecting the incident beam on the metasurface to be designed. For example, in a case that the incident beam is a Gaussian beam, and the light intensity distribution of the Gaussian beam reflects the distribution of the Gaussian spot, a radius of the Gaussian spot is determined according to the light intensity distribution of the Gaussian beam in the present embodiment. The determined radius is taken as one of the parameters of the incident beam.

Correspondingly, after the type of the outgoing beam is determined, the parameter of the outgoing beam may be determined based on the type of the outgoing beam. The parameter of the outgoing beam includes a light intensity distribution of the outgoing beam, where the light intensity distribution of the outgoing beam represents preset light spots formed on the diffraction plane after the outgoing beam is projected on the diffraction plane. For example, when the outgoing beam is determined to be a flat-top beam, the light intensity distribution of the flat-top beam represents a preset flat-top light spot distribution, the present embodiment determines a type of the light intensity distribution from the light intensity distribution of the flat-top beam. Types of the light intensity distribution may be of a rotationally symmetrical shape, such as being of a cylinder, or may be out of a rotationally symmetrical shape, such as being of a cuboid. Based on the light intensity distribution of the flat-top beam, the corresponding parameter of the outgoing beam may be determined.

Step 103: based on the parameters of the incident beam and the parameter of the outgoing beam, determining an initial value of a diffraction phase distribution. The diffraction phase distribution represents a phase distribution configured to modulate the incident beam to the outgoing beam.

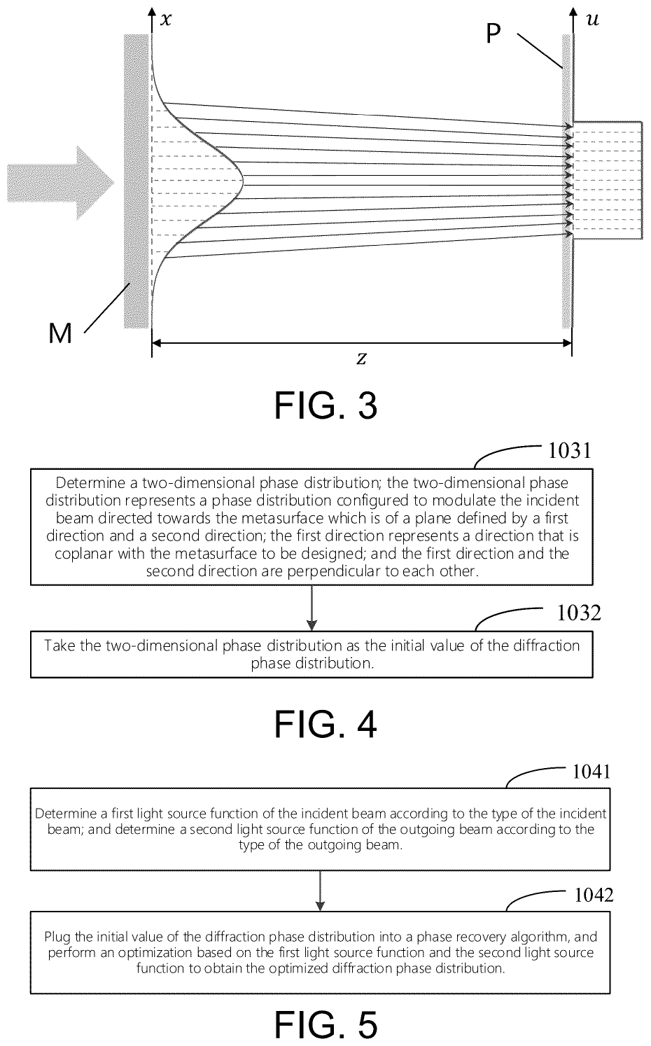

Beam shaping follows a physical principle of light intensity redistribution, by which, the phase configured to modulate the incident beam to the outgoing beam is calculated. That is to say, according to a light intensity distribution of the incident beam before being diffracted by the metasurface to be designed and a light intensity distribution (i.e., a diffraction result) of the outgoing beam obtained after the diffraction by the metasurface, the phase distribution configured to modulate the incident beam to the outgoing beam is determined. Referring to FIG. 3, a symbol M shown in FIG. 3 indicates the metasurface used for beam shaping, and a symbol P shown in FIG. 3 indicates the diffraction plane. An arrow on a left side of the metasurface shown in FIG. 3 represents the incident beam. It should be noted that since the diffraction phase distribution calculated based on the foregoing physical process usually results in diffraction, that is, the light intensity distribution of the outgoing beam has too smooth edges, and thus leads to poor shaping performances. Therefore, the calculated result of step 103 in the present embodiment is only the initial value of the diffraction phase distribution, which needs to be optimized subsequently.

Step 104: iteratively optimizing the diffraction phase distribution according to the type of the incident beam and the type of the outgoing beam to obtain an optimized diffraction phase distribution; generating a target phase distribution based on the optimized diffraction phase distribution; and generating a metasurface based on the target phase distribution.

Where, the initial value of the diffraction phase distribution obtained in the step 103 may be iteratively optimized through simulation based on the type of the incident beam and the type of the outgoing beam. In other words, a parameter to be optimized in the step 104 is the diffraction phase distribution. Through the iterative optimization, the initial value of the diffraction phase distribution is optimized to a diffraction phase distribution that yields better diffraction performances, which implies that the optimized diffraction phase distribution is obtained. The outgoing beam adjusted based on the optimized diffraction phase distribution has a light intensity distribution with edges being steeper and more obvious.

In the present embodiment, the finally-needed target phase distribution is generated according to the optimized diffraction phase distribution. The finally-needed target phase distribution is a phase distribution of the metasurface to be designed in the present embodiment. Specifically, a process of generating a metasurface based on the target phase distribution in the present embodiment may include: scanning a database of nanostructures with discrete phase points according to the obtained target phase distribution to select nanostructures that operate at wavelengths of the incident beam and are capable of covering phases ranging from 0 to 21, where the selected nanostructures meet requirements of the target phase distribution. After the completion of the design of the metasurface, the construction and the fabrication of the metasurface may be carried out.

In the method of designing the metasurface as provided in the present disclosure, the initial value of the diffraction phase distribution is firstly obtained by calculation and then the diffraction phase distribution is optimized (by starting from the initial value) to obtain an optimized diffraction phase distribution. Based on the optimized diffraction phase distribution, a target phase distribution for generating the metasurface to be designed is finally acquired. Instead of directly taking the diffraction phase distribution obtained based on a light intensity redistribution principle as the target phase distribution to generate the metasurface, the method disclosed herein takes the diffraction phase distribution as the initial value in optimization by simulation, which overcomes the problems in the existing technical solutions, for example, edges of the light intensity distribution of the outgoing beam are too smooth because the existing technical solutions solely use the light intensity redistribution principle to calculate the diffraction phase distribution. For another example, a simulation by using randomly generated initial values easily leads to falling into local optimum, causing the shaped outgoing beam to be poor in uniformity and have a light intensity distribution with a rough surface. Thus, a metasurface designed in the present disclosure is appropriate for beam shaping due to its advantages of being miniaturized and having lower fabrication difficulties and better shaping performances.

Optionally, referring to FIG. 4, the above-mentioned step 103 of “determining the initial value of the diffraction phase distribution based on the parameters of the incident beam and the parameter of the outgoing beam” may include the following steps 1031-1032.

Step 1031: determining a two-dimensional phase distribution; where the two-dimensional phase distribution represents a phase distribution configured to modulate the incident beam directed towards the metasurface which is of a plane defined by a first direction and a second direction; the first direction represents a direction that is coplanar with the metasurface to be designed; and the first direction and the second direction are perpendicular to each other.

Step 1032: taking the two-dimensional phase distribution as the initial value of the diffraction phase distribution.

Where, the two-dimensional phase distribution may be obtained through calculation, and the two-dimensional phase distribution is used as the initial value of the diffraction phase distribution. As the name implies, the two-dimensional phase distribution corresponds to a phase distribution of a two-dimensional plane configured to alter the light intensity distribution. Specifically, the two-dimensional plane is a plane defined by a first direction and a second direction that are perpendicular to each other. In the present embodiment, a direction that is coplanar with the metasurface is taken as the first direction. For example, a direction of an x-axis of the metasurface shown in FIG. 3 is taken as the first direction. That is, the plane defined by the first direction and the second direction is a plane where the metasurface to be designed is located. That is to say, the determined two-dimensional phase distribution is a phase distribution that is capable of modulating the light intensity distribution of the incident beam entering the metasurface to be designed. In the present embodiment, the two-dimensional phase distribution enables the incident beam to be diffracted into the outgoing beam after going through the metasurface. Therefore, the two-dimensional phase distribution is taken as the diffraction phase distribution to be optimized, i.e., the initial value of the diffraction phase distribution.

Optionally, the above-mentioned step 1031 of “determining the two-dimensional phase distribution” may include the following steps of A1 to A2.

Step A1: redistributing the light intensity distribution of the incident beam into the light intensity distribution of the outgoing beam to obtain a one-dimensional phase distribution; the one-dimensional phase distribution represents a phase distribution that modulates the incident beam directed in the first direction.

In theory, beam shaping is the redistribution of beam energy (light intensity). FIG. 3 shows a process of energy redistribution in beam shaping in a one-dimensional form: the energy within each small area (i.e., areas demarcated by dashed lines as shown in FIG. 3) of the incident beam is correspondingly distributed to a predetermined area on the diffraction plane. Based on this, in the present embodiment, the phase provided by the metasurface to be designed for modulating the incident beam directed to a certain direction that is coplanar with the metasurface is firstly determined, that is, a one-dimensional phase distribution is obtained. In other words, the one-dimensional phase distribution is used to change the light intensity distribution. For example, the direction of the x-axis of the metasurface is taken as the first direction, and the calculated phase distribution of the metasurface for modulating the incident light beam directed to the x-axis direction is taken as the one-dimensional phase distribution.

Step A2: determining the two-dimensional phase distribution according to a type of the light intensity distribution of the outgoing beam and the one-dimensional phase distribution.

In the present embodiment, after the one-dimensional phase distribution is determined in the above step A1, the type of the light intensity distribution of the outgoing beam to be obtained may be determined. For example, based on the light intensity distribution of the outgoing beam to be obtained, the determined type may be of a cylinder or may be of a cuboid. The specific type is not limited thereto. Based on the type of the light intensity distribution of the outgoing beam and the one-dimensional phase distribution, the two-dimensional phase distribution is obtained by calculation.

Optionally, a step of “determining the two-dimensional phase distribution based on the type of the light intensity distribution of the outgoing beam and the one-dimensional phase distribution” in the above-mentioned step 1032 may include the following steps B1-B2.

Step B1: in the case that the type of the light intensity distribution of the outgoing beam is of a cylinder, performing a rotational symmetry to the one-dimensional phase distribution to obtain the two-dimensional phase distribution.

In the present disclosure, the two-dimensional phase distribution is determined by different methods according to different types of the light intensity distribution of the outgoing beam. Specifically, when the outgoing beam is cylindrical, for example, in the case of shaping a Gaussian beam with circular symmetry into a cylindrical flat-top beam, both of the Gaussian beam and the flat-top beam are rotationally symmetrical, and the two-dimensional phase distribution can be obtained by performing the rotational symmetry to the one-dimensional phase distribution.

Step B2: in the case that the type of the light intensity distribution of the outgoing beam is of a cuboid, determining a phase distribution configured to modulate the incident beam directed in the second direction; superimposing the phase distribution configured to modulate the incident beam directed in the second direction and the one-dimensional phase distribution to obtain the two-dimensional phase distribution.

When the outgoing beam is cuboid-shaped, for example, in the case of shaping a Gaussian beam with circular symmetry into a cuboid-shaped flat-top beam, the required metasurface should perform the modulation along the first direction and the second direction. That is, on the basis of the one-dimensional phase distribution corresponding to the first direction, the phase distribution configured to modulate the incident beam directed in the second direction is superimposed, and the two-dimensional phase distribution is obtainable by integrating the modulation phase corresponding to the first direction and the modulation phase corresponding to the second direction.

Optionally, the one-dimensional phase distribution satisfies:

$${φ}_{1} ( x ) = \frac{2 π}{λ z} {\int }_{0}^{x} [ u ( t ) - t ] dt .$$

In the case that the type of the light intensity distribution of the outgoing beam is of a cylinder, the two-dimensional phase distribution satisfies:

$${φ}_{2} ( x , y ) = {φ}_{1} ( \sqrt{{x}^{2} + {y}^{2}} ) .$$

Where, referring to FIG. 3, φ₁(x) represents the one-dimensional phase distribution; x represents a position on the metasurface in the first direction; λ represents the wavelength of the incident beam; z represents a distance that the outgoing beam travels to a diffraction plane; u(t) represents a conversion relationship between a position u of the light intensity distribution of the outgoing beam and a position t of the incident beam in the first direction, and t represents an integral variable; φ₂(x, y) represents the two-dimensional phase distribution; y represents a position on the metasurface in the second direction.

Optionally, in the case that the type of the light intensity distribution of the outgoing beam is of a cuboid, the two-dimensional phase distribution satisfies:

$${φ}_{2} ( x , y ) = {φ}_{1 x} ( x ) + {φ}_{1 y} ( y ) ;$$

and

$${φ}_{1 x} ( x ) = \frac{2 π}{λ z} {\int }_{0}^{x} [ {u}_{x} ( t ) - t ] dt ; {φ}_{1 y} ( y ) = \frac{2 π}{λ z} {\int }_{0}^{y} [ {u}_{y} ( t ) - t ] dt ;$$

where, referring to FIG. 3, φ₂(x, y) represents the two-dimensional phase distribution; λ represents the wavelength of the incident beam; z represents a distance that the outgoing beam travels to a diffraction plane; t represents an integral variable; φ₁ₓ(x) represents a one-dimensional phase distribution in the first direction; x represents a position on the metasurface in the first direction; uₓ(t) represents a conversion relationship between a position uₓ of the light intensity distribution of the outgoing beam in the first direction x and a position t of the incident beam in the first direction x; φ_{1y}(y) represents a one-dimensional phase distribution in the second direction; y represents a position on the metasurface in the second direction; u_{y}(t) represents a conversion relationship between a position u_{y} of the light intensity distribution of the outgoing beam in the second direction y and a position t of the incident beam in the second direction y.

Where, based on the principle that beam shaping is to redistribute light intensity, the Formula 1 is obtained and shown as follows:

$${\int }_{0}^{x} {I}_{i} ( t ) d t = {\int }_{0}^{u ( x )} {I}_{t} ( t ) d t .$$

In the Formula 1, lᵢ(x) is the light intensity distribution of the incident beam, and lₜ (u) is the light intensity distribution of the outgoing beam that is projected onto the diffraction plane after being shaped by the beam shaper. According to the Formula 1, the coordinate conversion relationship u(t) is obtained based on the light intensity distribution of the incident beam and the light intensity distribution of the outgoing beam. During the foregoing light intensity conversion, as for the diffraction plane at a distance z from the metasurface to be designed, a deflection angle θ of respective light rays satisfies the following relationship (i.e., Formula 2):

$$tan θ = \frac{u ( x ) - x}{z} ;$$

and the one-dimensional phase distribution φ₁(x) satisfies the following relationship (i.e. Formula 3):

$$sin θ = \frac{λ}{2 π} \times \frac{d {φ}_{1} ( x )}{d x} .$$

Since the deflection angles caused by the metasurface used for beam shaping are not too large, tanθ is approximately equal to sinθ in the present embodiment, thus, according to the Formula 2 and the Formula 3, Formula 4 is obtained and shown as follows:

$${φ}_{1} ( x ) = \frac{2 π}{λ z} {\int }_{0}^{x} [ u ( t ) - t ] d t ,$$

which is a formula that the one-dimensional plate distribution satisfies.

In the present embodiment, as for the case of converting a Gaussian beam into a flat-top beam, Formula 5 is calculated based on the light intensity distribution of the Gaussian beam

$${I}_{i} ( x ) = exp ( - \frac{2 {x}^{2}}{{ω}_{1}^{2}} ) ,$$

and the obtained Formula 5 is shown

$$u ( x ) = \frac{{ω}_{1} {ω}_{2}}{\sqrt{2 π}} {\int }_{0}^{x} exp ( - \frac{2 {t}^{2}}{{ω}_{1}^{2}} ) dt ,$$

where, ω₁ is a Gaussian beam radius at which the light intensity is decreased to 1/e²; ω₂ is a half-width value of the flat-top beam. Formula 6 is obtained by plugging the Formula 5 into the Formula 4, and the obtained Formula 6 is shown as follows:

$${φ}_{1} ( x ) = \frac{2 π}{λ z} \{ \frac{{ω}_{1} {ω}_{2}}{\sqrt{2 π}} [ exp ( - \frac{2 {x}^{2}}{{ω}_{1}^{2}} ) + x {\int }_{0}^{x} exp ( - \frac{2 {t}^{2}}{{ω}_{1}^{2}} ) dt - 1 ] - \frac{1}{2} {x}^{2} \} .$$

In the above Formula 6, φ₁(x) aims at the shaping of a one-dimensional curve, that is, φ₁(x) is the one-dimensional phase distribution. However, the metasurface to be designed is a two-dimensional planar device, thus, it is needed to accordingly convert the above Formula 6 based on the type of the light intensity distribution of the outgoing beam to obtain a phase distribution applied to the two-dimensional shaping, and the obtained phase distribution is the two-dimensional phase distribution.

Specifically, for the case of shaping a Gaussian beam with circular symmetry into a cylindrical flat-top beam, the two-dimensional phase distribution φ₂(x, y) satisfies:

$${φ}_{2} ( x , y ) = {φ}_{1} ( \sqrt{{x}^{2} + {y}^{2}} ) ;$$

for shaping a Gaussian beam with circular symmetry into a cuboid-shaped flat-top beam (being square at a x-y cross-section), the two-dimensional phase distribution φ₂(x, y) satisfies: φ₂(x,y)=φ₁ₓ(x)+φ_{1y}(y). It should be noted that for other cases of beam shaping, the two-dimensional phase distribution φ₂(x, y) provided by the metasurface is also calculated based on the light intensity distribution of the incident beam and the outgoing beam through the foregoing analysis method.

Optionally, referring to FIG. 5, a step of “iteratively optimizing the diffraction phase distribution based on the type of the incident beam and the type of the outgoing beam to obtain the optimized diffraction phase distribution” in the above-mentioned step 104 may include the following steps 1041-1042.

Step 1041: determining a first light source function of the incident beam according to the type of the incident beam; and determining a second light source function of the outgoing beam according to the type of the outgoing beam.

Where, through the known type of the incident beam and the known type of the outgoing beam, the first light source function of the incident beam and the second light source function of the outgoing beam are determined. The first light source function and the second light source function are important parameters for optimization by simulation.

Step 1042: plugging the initial value of the diffraction phase distribution into a phase recovery algorithm, and performing an optimization based on the first light source function and the second light source function to obtain the optimized diffraction phase distribution.

Based on the first light source function and the second light source function determined in the above step 1041, an optimization by simulation is performed. In the present embodiment, the target of optimization by simulation is the diffraction phase distribution. Specifically, the initial value of the diffraction phase distribution determined in the above step 103 is plugged into the phase recovery algorithm, such as the G-S algorithm (Gerchberg-Saxton algorithm) or the iterative Fourier transform algorithm. By combining the first light source function and the second light source function, the diffraction phase distribution is optimized through simulation to obtain the optimized diffraction phase distribution. For example, after a light source function of the Gaussian beam and a light source function of the flat-top beam are determined in the above step 1041, the initial value of the diffraction phase distribution determined in the above step 103 is plugged into the G-S algorithm for iterative optimization to obtain the optimized diffraction phase distribution.

Since the conventional phase recovery algorithms are very sensitive to an initial value of a phase to be iterated, the present embodiment plugs the initial value of the diffraction phase distribution calculated based on the light intensity energy distribution into the initial phase of the phase recovery algorithm. By optimizing the diffraction phase distribution, a process of the iterative optimization does not fall into local optimum, which avoids poor uniformity of the outgoing beam, for example, the flat-top beam has poor uniformity; the light intensity distribution curved surface is relatively rough. In addition, by the aforementioned method, a phase (i.e., the optimized diffraction phase distribution) with better modulation performances is obtained and is capable of allowing the light intensity distribution of the outgoing beam to have steeper edges, thereby improving the performance of the beam shaping.

Optionally, a step of “generating a target phase distribution based on the optimized diffraction phase distribution” in the above step 104 may include the following steps C1 or C2.

Step C1: taking the optimized diffraction phase distribution as the target phase distribution.

Where, the optimized diffraction phase distribution is directly taken as the target phase distribution, i.e., a phase distribution corresponding to the metasurface to be designed. Based on the target phase distribution (optimized diffraction phase distribution), a metasurface which is capable of realizing beam shaping and having good shaping performances is generated.

Step C2: superimposing an additional phase distribution on the optimized diffraction phase distribution to obtain the target phase distribution; where the additional phase distribution represents a phase distribution configured for collimating the incident beam or configured for focusing the outgoing beam.

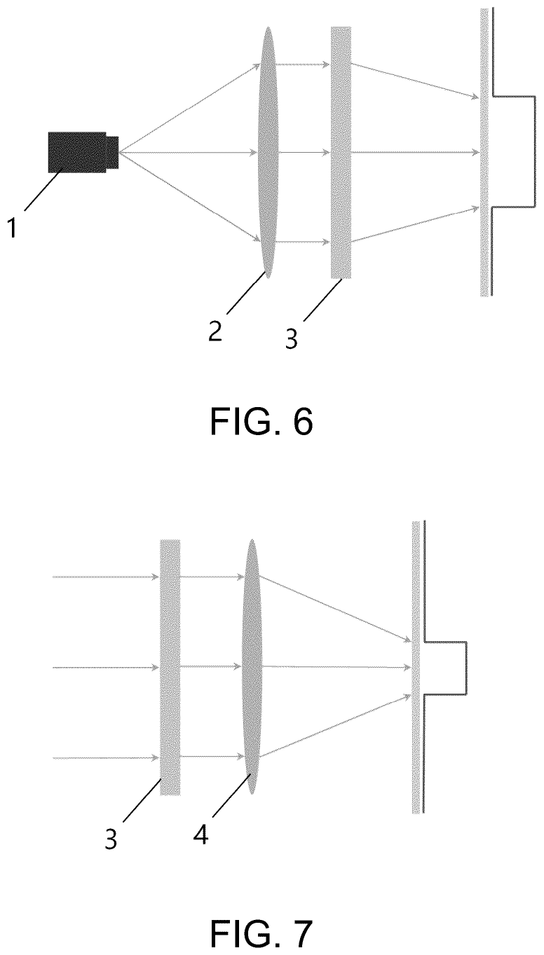

In some scenarios that involve beam shaping, such as one scenario shown in FIG. 6, a Gaussian beam emitted from a laser source (which is indicated with the reference numeral 1 in FIG. 6) has a certain divergence angle, and thus usually needs to be collimated by a collimating lens (which is indicated with the reference numeral 2 in FIG. 6) and then goes through an optical element used for beam shaping (such as a metasurface of the present embodiment which is indicated with the reference numeral 3 in FIG. 6) to shape the beam. Or, such as one scenario shown in FIG. 7, the outgoing beam (flat-top beam) after the shaping needs to pass through a focusing lens (which is indicated with the reference numeral 4 in FIG. 7) to be coupled to a back-end optical device. Therefore, the beam collimating or the beam focusing based on lenses is also a process of phase modulation of the beam. By superimposing the modulation phase distribution of the lenses with the modulation phase distribution of the beam shaper, two functions of collimation (or focusing) and shaping can be integrated together to form a single optical element.

Based on this, in the present embodiment, an additional phase distribution may be superimposed on the optimized diffraction phase distribution according to the actual situation to obtain the target phase distribution required to generate the metasurface. Where, the additional phase distribution is also a phase distribution that modulates the light beam. The additional phase distribution is different from the optimized diffraction phase distribution in that: the additional phase distribution can realize collimating of the incident beam or focusing of the outgoing beam. In other words, when the actual situation requires the metasurface to shape the incident beam while collimating the incident beam or focusing the outgoing beam, it is needed in the present embodiment to superimpose the additional phase distribution on the optimized diffraction phase distribution to obtain the target phase distribution that is finally required. It should be noted that a phase distribution used to collimate and a phase distribution used to focus are the same in essence.

Optionally, the additional phase distribution satisfies:

$${φ}_{3} ( x , y ) = - \frac{2 π}{λ} ( \sqrt{{x}^{2} + {y}^{2} + {f}^{2}} - f ) ;$$

where, φ₃(x, y) represents an additional phase distribution of the metasurface to be designed at a position (x, y); λ represents the wavelength of the incident beam; f represents a focal length of the metasurface to be designed. It should be noted that in the case that the metasurface to be designed has dual functions of collimation and shaping, f represents a distance between the laser source and the metasurface. In the case that the metasurface to be designed has dual functions of focusing and shaping, f relates to the shrinkage of the outgoing beam. In the present embodiment, the specific value of f is designed according to a shrinkage ratio. The present embodiment, the additional phase distribution may be calculated according to the above formula that the additional phase distribution satisfies.

A beam shaper is provided according to an embodiment. Referring to FIG. 2, the beam shaper includes a metasurface (which is indicated with the reference symbol M in FIG. 2) designed by any of the above design methods. The beam shaper of the present disclosure is thinner and lighter due to the use of the metasurface, thus has the advantages of compact size and easy portability, thereby avoiding the problem that the traditionally-used lens set occupies lots of space. Since the materials used by the metasurface are mainly heat-resistant materials, such as silicon, the phase modulation of the metasurface is hardly affected by the temperature variations. Thus, when the incident beam with relatively larger power passes through the metasurface, the metasurface still maintains high performance. In addition, the target phase distribution of the metasurface obtained based on this design method achieves beam shaping with high transmission efficiency. For example, the flat-top beam has satisfactory plateau uniformity and basically does not have side lobes.

Optionally, a radius of the metasurface is greater than or equal to a radius of a light spot projected by the incident beam on the metasurface.

In the present embodiment, in order to acquire sufficient energy for redistribution of light intensity, a size of the metasurface should be large enough to cover the light intensity distribution of the incident beam. That is, the radius of the metasurface is greater than or equal to the radius of the light spot projected by the incident beam on the metasurface. Preferably, the radius of the metasurface is greater than or equal to 3 times the radius of the light spot. In this case, the situation that the edge of the generated flat-top beam is not steep enough and the flat-top has slight fluctuations can be effectively avoided.

### Embodiment 1

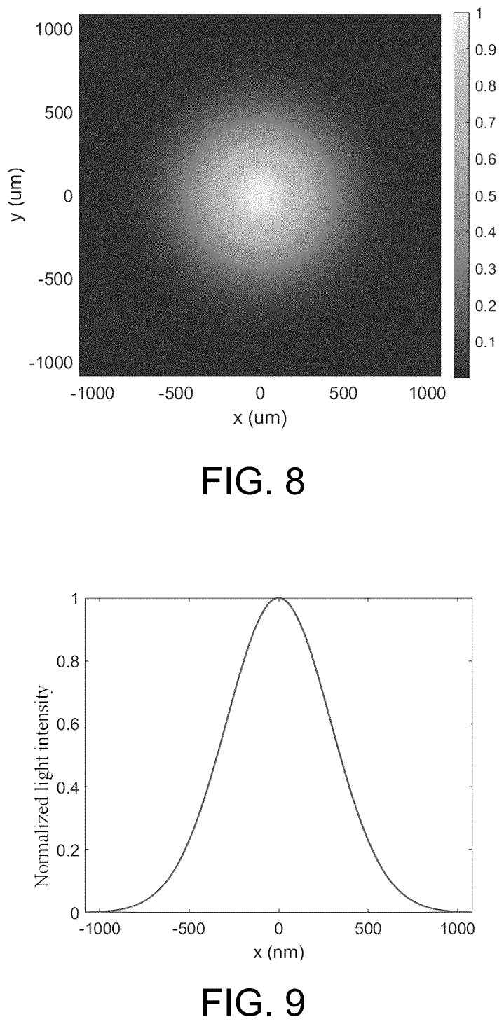

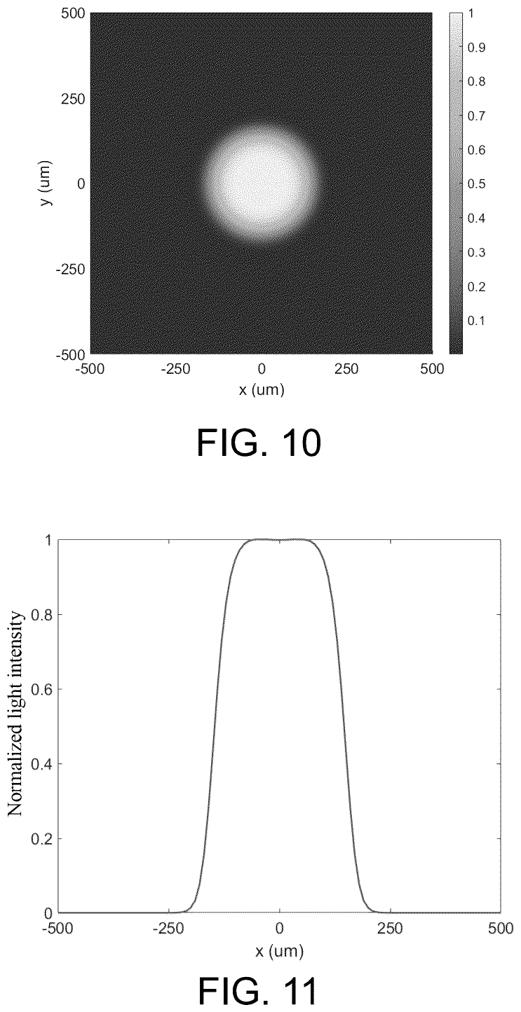

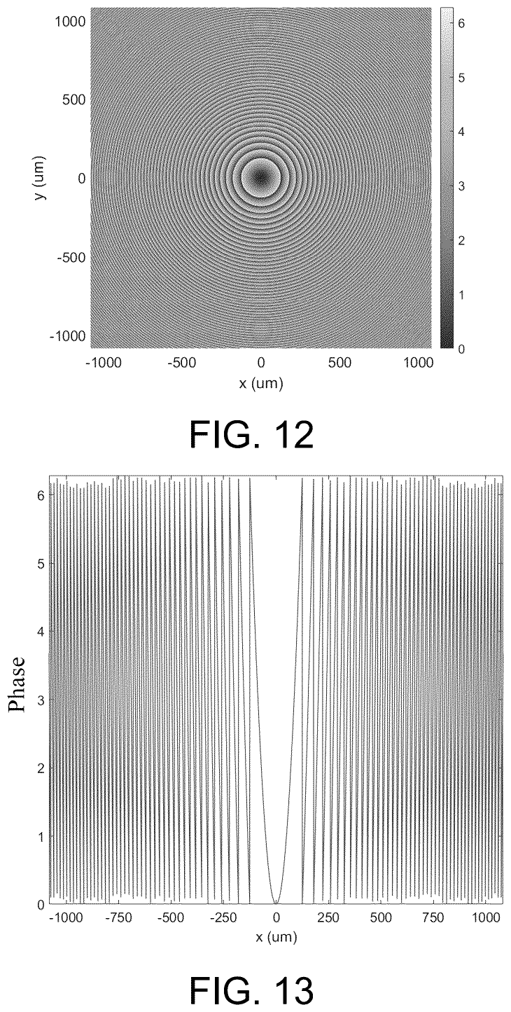

As for a Gaussian beam having a wavelength of 940 nm and being capable of projecting a light spot with a radius of 291 μm on the beam shaper (metasurface), where the Gaussian beam projected on a surface of the beam shaper has a light intensity distribution as shown in FIG. 8 and has a cross-sectional distribution at y=0 as shown in FIG. 9, the use of a beam shaper with a size of 2.16 mm is able to shape the Gaussian beam into a flat-top beam with a radius of 175 μm on the diffraction plane 4.8 mm away from the beam shaper. Referring to FIG. 10 and FIG. 11, FIG. 10 is a schematic diagram of a light intensity distribution of the flat-top beam projected on the diffraction plane. FIG. 11 is a schematic diagram of a cross-sectional distribution of the flat-top beam at y=0. A phase distribution of the beam shaper is shown in FIG. 12. FIG. 13 is a schematic diagram of a cross-sectional distribution of the phase distribution of the beam shaper at y=0.

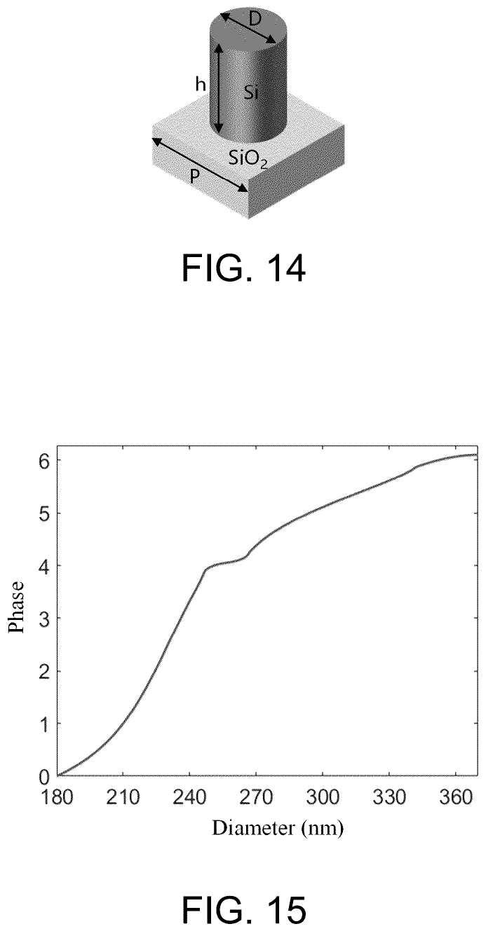

The generation of a metasurface that has the above phase distribution for beam shaping needs nanostructures that operate at a wavelength of 940 nm and that have satisfactory phase modulation. In embodiment 1, Si nanopillars on a SiO2 substrate are selected from a nanostructure database. The selected nanopillars have a height (h) of 600 nm and a period (P) of 550 nm. The refractive index of SiO2 is 1.45 and the refractive index of Si is 3.42. One of the nanopillars is shown in FIG. 14. The relationship between the diameter D of a simulated nanopillar and the modulation phase of the simulated nanopillar is shown in FIG. 15. It is determined that the selected nanopillars have the phase coverage of 0˜2π, and are highly efficient at phase modulation, which are applicable to the generation of the metasurface that serves as the beam shaper.

### Embodiment 2

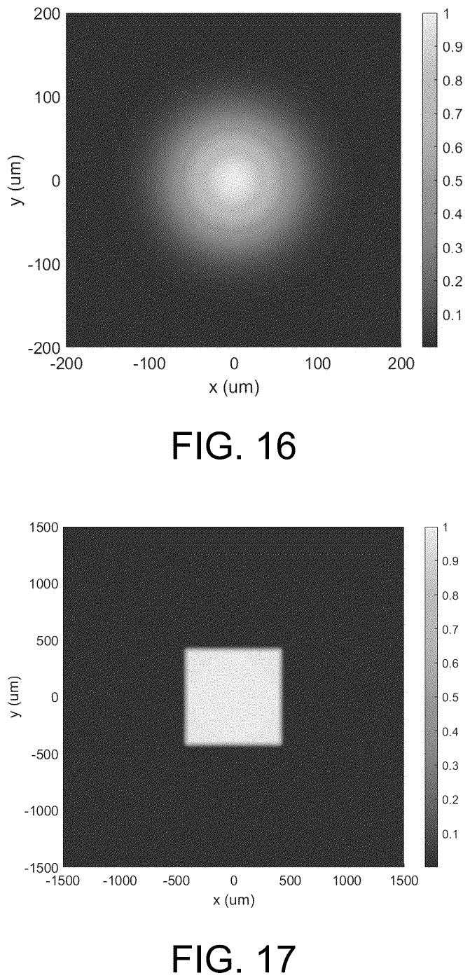

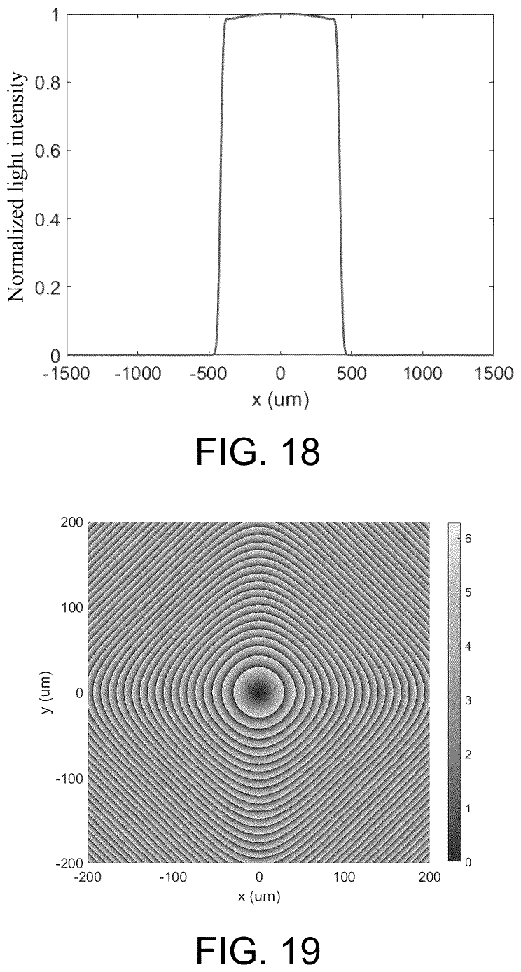

As for a Gaussian beam with a wavelength of 808 nm and being capable of projecting a light spot with a radius of 60 μm on the beam shaper (metasurface), where the light spot has a light intensity distribution shown in FIG. 16, the use of a beam shaper with a size of 2.16 mm is able to shape the Gaussian beam into a flat-top beam with a width of 440 μm on the diffraction plane 4.8 mm away from the beam shaper. Referring to FIG. 17 and FIG. 18, FIG. 17 is a schematic diagram of a light intensity distribution of the flat-top beam projected on the diffraction plane. FIG. 18 is a schematic diagram of a cross-sectional distribution of the flat-top beam at y=0. A phase distribution of the beam shaper is shown in FIG. 19.

### Embodiment 3

For a Gaussian beam that is not reciprocal in an x direction and a y direction, specifically, the light intensity distribution of the Gaussian beam satisfies:

$$I ( x , y ) = exp ( - \frac{{x}^{2}}{{ω}_{11}^{2} / 2} - \frac{{y}^{2}}{{ω}_{12}^{2} / 2} ) ;$$

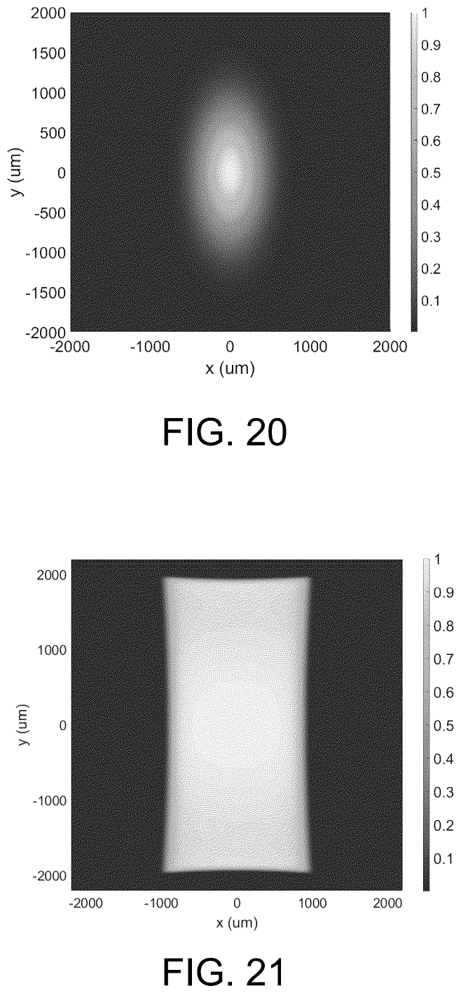

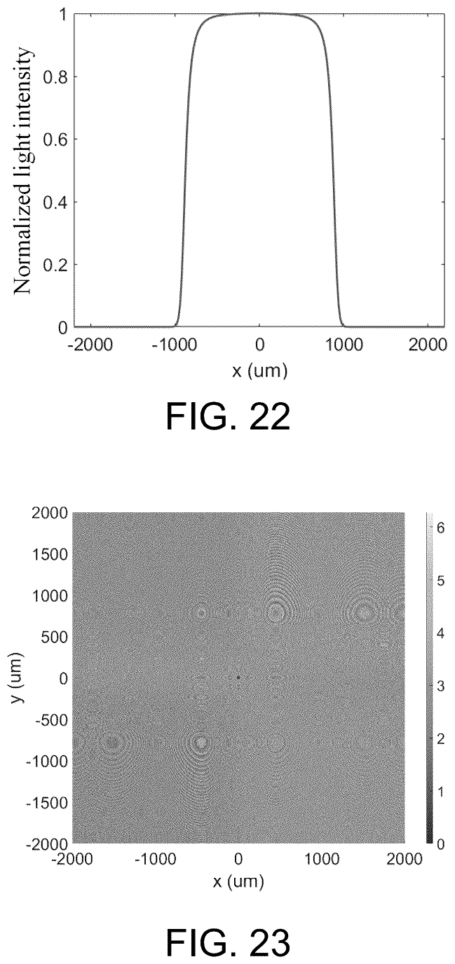

if the Gaussian beam is shaped into a flat-top beam having a light field that satisfies: E (x, y)=1, and |x|<ω₂₁, |y|<ω₂₂; where, ω₁₁ represents a half-width of the light intensity distribution of the Gaussian beam projected on the surface of the beam shaper in the x direction, and ω₁₁ is equal to 0.7 mm; ω₁₂ represents a half-width of the light intensity distribution of the Gaussian beam projected on the surface of the beam shaper in the y direction, and ω₂₂ is equal to 2 mm; where, the wavelength of the Gaussian beam is 647 nm. Herein, the phase distribution of the beam shaper (metasurface) satisfies φ₂(x,y)=φ₁(x)|_{ω}_{₁}_{=ω}_{₁₁}_{,ω}_{₂}_{=ω}_{₂₁}+φ₁(y)|_{ω}_{₁}_{=ω}_{₁₂}_{,ω}_{₂}_{=ω}_{₂₂}. The light intensity distribution of the Gaussian beam is shown in FIG. 20. The light intensity distribution of the flat-top beam is shown in FIG. 21. FIG. 22 is a schematic diagram of a cross-sectional distribution of the flat-top beam at y=0. A phase distribution of the beam shaper is shown in FIG. 23.

The method of designing the metasurface of the present disclosure is described in detail above, and the method may be implemented by the corresponding devices. A device of designing a metasurface of the present embodiment will be described in detail below.

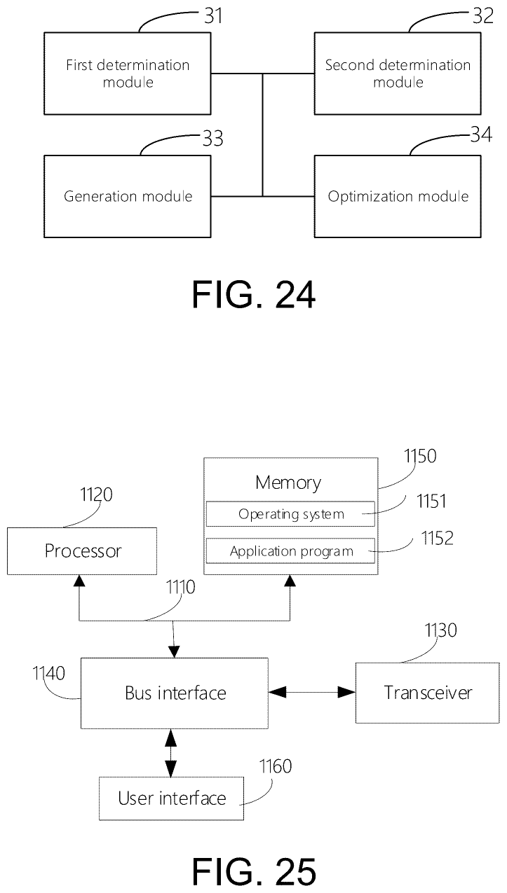

FIG. 24 schematically shows a device of designing a metasurface according to an embodiment of the present disclosure. As shown in FIG. 24, the device of designing the metasurface includes a first determination module 31, a second determination module 31, an establishment module 33 and an optimization module 34.

The first determination module 31 is configured to determine a type of an incident beam and parameters of the incident beam; the parameters of the incident beam include a wavelength of the incident beam and a light intensity distribution of the incident beam.

The second determination module 32 is configured to determine a type of an outgoing beam and a parameter of the outgoing beam. The parameter of the outgoing beam includes a light intensity distribution of the outgoing beam.

The generation module 33 is configured to determine an initial value of a diffraction phase distribution based on the parameters of the incident beam and the parameter of the outgoing beam. The diffraction phase distribution represents a phase distribution configured to modulate the incident beam to the outgoing beam.

The optimization module 34 is configured to iteratively optimize the diffraction phase distribution based on the type of the incident beam and the type of the outgoing beam to obtain an optimized diffraction phase distribution. The optimization module 34 is also configured to generate a target phase distribution according to the optimized diffraction phase distribution and generate the metasurface according to the target phase distribution.

Optionally, the generation module 33 includes a first generation sub-module for two-dimensional calculation and a second generation sub-module for determining the initial value.

The first generation sub-module is configured to determine a two-dimensional phase distribution. The two-dimensional phase distribution represents a phase distribution configured to modulate the incident beam directed towards the metasurface which is of a plane defined by a first direction and a second direction. The first direction represents a direction that is coplanar with the metasurface to be designed; and the first direction and the second direction are perpendicular to each other.

The second generation sub-module is configured to take the two-dimensional phase distribution as the initial value of the diffraction phase distribution.

Optionally, the first generation sub-module includes a one-dimensional calculation unit and a two-dimensional phase distribution determination unit.

The one-dimensional calculation unit is configured to redistribute the light intensity distribution of the incident beam into the light intensity distribution of the outgoing beam to obtain a one-dimensional phase distribution. The one-dimensional phase distribution represents a phase distribution that modulates the incident beam directed in the first direction. The first direction represents a direction that is coplanar with the metasurface to be designed.

The two-dimensional phase distribution determination unit is configured to determine the two-dimensional phase distribution according to a type of the light intensity distribution of the outgoing beam and the one-dimensional phase distribution.

Optionally, the incident beam is a Gaussian beam. The outgoing beam is a flat-top beam.

Optionally, the two-dimensional phase distribution determination unit includes a first calculation sub-unit and a second calculation sub-unit.

The first calculation sub-unit is configured to perform a rotational symmetry to the one-dimensional phase distribution when the type of the light intensity distribution of the outgoing beam is of a cylinder, so as to obtain the two-dimensional phase distribution.

When the type of the light intensity distribution of the outgoing beam is of a cuboid, the second calculation sub-unit is configured to determine a phase distribution used to modulate the incident beam directed in the second direction, and is also configured to superimpose the phase distribution configured to modulate the incident beam directed in the second direction and the one-dimensional phase distribution to obtain the two-dimensional phase distribution.

Optionally, the one-dimensional phase distribution satisfies:

$${φ}_{1} ( x ) = \frac{2 π}{λ z} {\int }_{0}^{x} [ u ( t ) - t ] dt .$$

In the case that the type of the light intensity distribution of the outgoing beam is of a cylinder, the two-dimensional phase distribution satisfies:

$${φ}_{2} ( x , y ) = {φ}_{1} ( \sqrt{{x}^{2} + {y}^{2}} ) ,$$

where, φ₁(x) represents the one-dimensional phase distribution; x represents a position on the metasurface in the first direction; λ represents the wavelength of the incident beam; z represents a distance that the outgoing beam travels to a diffraction plane; u(t) represents a conversion relationship between a position u of the light intensity distribution of the outgoing beam and a position t of the incident beam in the first direction, and t represents an integral variable; φ₂(x, y) represents the two-dimensional phase distribution; y represents a position on the metasurface in the second direction.

Optionally, in the case that the type of the light intensity distribution of the outgoing beam is of a cuboid, the two-dimensional phase distribution satisfies:

$${φ}_{2} ( x , y ) = {φ}_{1 x} ( x ) + {φ}_{1 y} ( y ) ;$$

$${φ}_{1 x} ( x ) = \frac{2 π}{λ z} {\int }_{0}^{x} [ {u}_{x} ( t ) - t ] dt ; {φ}_{1 y} ( y ) = \frac{2 π}{λ z} {\int }_{0}^{y} [ {u}_{y} ( t ) - t ] dt ;$$

where, φ₂(x, y) represents the two-dimensional phase distribution; λ represents the wavelength of the incident beam; z represents a distance that the outgoing beam travels to a diffraction plane; t represents an integral variable; φ₁ₓ(x) represents a one-dimensional phase distribution in the first direction; x represents a position on the metasurface in the first direction; uₓ(t) represents a conversion relationship between a position uₓ of the light intensity distribution of the outgoing beam in the first direction x and a position t of the incident beam in the first direction x; φ_{1y}(y) represents a one-dimensional phase distribution in the second direction; y represents a position on the metasurface in the second direction; u_{y}(t) represents a conversion relationship between a position u_{y} of the light intensity distribution of the outgoing beam in the second direction y and a position t of the incident beam in the second direction y.

Optionally, the optimization module 34 includes a light source function sub-module and an iterative optimization sub-module.

The light source function sub-module is configured to determine a first light source function of the incident beam according to the type of the incident beam and is also configured to determine a second light source function of the outgoing beam according to the type of the outgoing beam.

The iterative optimization sub-module is configured to plug the initial value of the diffraction phase distribution into a phase recovery algorithm and is also configured to perform an optimization based on the first light source function and the second light source function to obtain the optimized diffraction phase distribution.

Optionally, the optimization module 34 includes a first optimization sub-module for direct determination or a second optimization sub-module for indirect determination.

The first optimization sub-module for direct determination is configured to take the optimized diffraction phase distribution as the target phase distribution.

Or, the second optimization sub-module for indirect determination is configured to superimpose an additional phase distribution on the optimized diffraction phase distribution to obtain the target phase distribution. The additional phase distribution represents a phase distribution configured for collimating the incident beam or configured for focusing the outgoing beam.

Optionally, the additional phase distribution satisfies:

$${φ}_{3} ( x , y ) = - \frac{2 π}{λ} ( \sqrt{{x}^{2} + {y}^{2} + {f}^{2}} - f ) ;$$

where, φ₃(x, y) represents an additional phase distribution of the metasurface to be designed at a position (x, y); λ represents the wavelength of the incident beam; f represents a focal length of the metasurface to be designed.

By the device as provided in the present embodiment, an initial value of the diffraction phase distribution is obtained by calculation. The diffraction phase distribution is optimized (by starting from the initial value) to obtain an optimized diffraction phase distribution. Based on the optimized diffraction phase distribution, a target phase distribution for generating the metasurface is finally acquired. Instead of directly taking the diffraction phase distribution obtained based on a light intensity redistribution principle as the target phase distribution to generate the metasurface, the method disclosed herein takes the diffraction phase distribution as the initial value in optimization by simulation, which overcomes the problems in the existing technical solutions, for example, edges of the light intensity distribution of the outgoing beam are too smooth because the existing technical solutions solely use the light intensity redistribution principle to calculate the diffraction phase distribution. For another example, a simulation by using randomly generated initial values easily leads to falling into local optimum, causing the shaped outgoing beam to be poor in uniformity and have a light intensity distribution with a rough surface. Thus, a metasurface designed in the present disclosure is appropriate for beam shaping due to its advantages of being miniaturized and having lower fabrication difficulties and better shaping performances.

It should be noted that the device of designing the metasurface implements the corresponding functions by functional modules as described above. However, the segmentation among the functional modules is only illustrative. In practical use, the above functions may be allocated to different functional modules as needed. That is, internal structures of the device are divided into different functional modules to complete all or a part of the functions described above. In addition, the device of designing the metasurface and the method of designing the metasurface in the embodiments as described above share the same concept. The specific implementation process of the device of designing the metasurface is similar to the method of designing the metasurface, and will not be repeated herein.

According to one aspect of the present disclosure, a computer program product is provided. The computer program product includes a computer program including program code for executing a method shown in the flowchart. In an embodiment, the computer program may be downloaded from network via communications and may be installed. The computer program is executed by the processor to execute the method of designing the metasurface provided by the present embodiment.

In addition, electronic equipment is provided according to an embodiment of the present disclosure. The electronic equipment includes a bus, a transceiver, a memory, a processor, and a computer program stored in the memory and executable on the processor. The transceiver, the memory, and the processor are connected by the bus. The computer program is executed by the processor, such that respective steps of the method of designing the metasurface are implemented and the same technical effect is achieved. Further details will not be discussed herein for the purpose of avoiding repetition.

Specifically, referring to FIG. 25, electronic equipment is provided in the present embodiment. The electronic equipment includes a bus 1110, a processor 1120, a transceiver 1130, a bus interface 1140, a memory 1150 and a user interface 1160.

In the present embodiment, the electronic equipment further includes a computer program. The computer program is stored in the memory 1150 and is executable on the processor 1120. The computer program is executed by the processor 1120 to implement respective steps of the method of designing the metasurface as described above.

The transceiver 1130 is configured to receive and transmit data under the control of the processor 1120.

In the present embodiment, the bus 1110 represents a bus framework. The bus 1110 may include any number of interconnected buses and bridges. The bus 1110 is configured to connect various circuits of one or more processors represented by the processor 1120 and a memory represented by the memory 1150.

The bus 1110 represents one or more of any one of a plurality of types of bus structures. The bus 1110 includes a memory bus and a local bus of any structure in a memory controller, a peripheral bus, an Accelerate Graphical Port (AGP), a processor or an architecture using various buses. For the purpose of illustration rather than limitation, the architecture includes an Industry Standard Architecture (ISA) bus, a Micro Channel Architecture (MCA) bus, an Enhanced ISA (EISA) bus, a Video Electronics Standards Association (VESA) bus, a Peripheral Component Interconnect (PCI) bus.

The processor 1120 may be an integrated circuit chip with signal processing capabilities. During the implementation processes, respective steps of the method described in the above embodiments may be completed by instructions in the form of integrated logic circuits in hardware or software in the processor. The processor may be a general-purpose processor, a Central Processing Unit (CPU), a Network Processor (NP), a Digital Signal Processor (DSP), an Application Specific Integrated Circuit (ASIC), a Field Programmable Gate Array (FPGA), a Complex Programmable Logic Device (CPLD), a Programmable Logic Array (PLA), a Microcontroller Unit (MCU) or other equipment such as a programmable logic device, a discrete gate, a transistor logic device, a discrete hardware component, which are capable of implementing or executing the method, respective steps and logical block diagrams disclosed in the present embodiment. For example, the processor may be a single-core processor or a multi-core processor. The processor may be integrated into a single chip or located on multiple different chips.

The processor 1120 may be a microprocessor or any conventional processor. The steps of the method disclosed in the present embodiment may be directly executed by a hardware decoding processor, or may be executed by a combination of a hardware module and a software module in a decoding processor. The software module may be provided in a readable storage media including Random Access Memory (RAM), Flash Memory (Flash Memory), Read-Only Memory (ROM), Programmable Read-Only Memory (PROM), Erasable PROM (EPROM) and a register, which are known in the art. The readable storage medium is located in the memory. The processor reads information in the memory and completes the steps of the method in combination with the hardware of the processor.

The bus 1110 may also realize the circuit connection of other devices such as peripheral equipment, a voltage regulator or power management circuit. The bus interface 1140 provides an interface between the bus 1110 and the transceiver 1130, which are known in the art. The general knowledge will not be described herein.

The transceiver 1130 may be an element or may be multiple elements, such as multiple receivers and multiple transmitters. The transceiver 1130 is configured to serve as a unit for communicating with various other devices over a transmission medium. For example, the transceiver 1130 receives external data from other devices, and the transceiver 1130 is used to send the processed data by the processor 1120 to other devices. Depending on the type of the computer system, a user interface 1160 may also be provided. The user interface 1160 may be a touch screen, a physical keyboard, a monitor, a mouse, a speaker, a microphone, a trackball, a joystick or a stylus.

It should be understood that in the present embodiment, the memory 1150 may further include memories remotely located relative to the processor 1120. The memories may be connected to a server through a network. One or more parts of the network may be an ad hoc network, an intranet, an extranet, a virtual private network (VPN), a local area network (LAN), a wireless local area network (WLAN), a wide area network (WAN), a wireless wide area network (WWAN), a metropolitan area network (MAN), Internet, a public switched telephone network (PSTN), a plain old telephone service (POTS) network, a cellular telephone network, a wireless network, a wireless fidelity (Wi-Fi) network or a combination thereof. The combination includes at least two kinds of networks listed herein. For example, the cellular telephone network and the wireless network may be a Global System for Mobile Communications (GSM), Code Division Multiple Access (CDMA), Worldwide Interoperability for Microwave Access (WiMAX), General Packet Radio Service (GPRS), a Broadband CDMA (WCDMA) system, a Long Term Evolution (LTE) system, an LTE Frequency Division Duplex (FDD) system, an LTE Time Division Duplex (TDD) system, a Long Term Evolution Advanced (LTE-A) system, a Universal Mobile Telecommunications (UMTS) system, an Enhanced Mobile Broadband (eMBB) system, a massive Machine Type of Communication (mMTC) system, an Ultra Reliable Low Latency Communications (uRLLC) system, etc.

It should be understood that the memory 1150 in the present embodiment may be a volatile memory, a non-volatile memory, or a combination thereof. Where, the non-volatile memory may be a Read-Only Memory (ROM), a Programmable ROM (PROM), and an Erasable PROM (EPROM), an Electrically EPROM (EEPROM) or a Flash Memory.

The volatile memory may be a Random Access Memory (RAM), which is used as an external cache. The RAM may be of various types. For the purpose of illustration but not limitation, the RAM may be a Static RAM (SRAM), a Dynamic RAM (DRAM), a Synchronous DRAM (SDRAM), a Double Data Rate SDRAM (DDRSDRAM), an Enhanced SDRAM (ESDRAM), a synchronous link DRAM (SLDRAM) or a Direct Rambus RAM (DRRAM). The memory 1150 described in the present embodiment may be any of memories listed herein or may be any of other appropriate memories, and the present embodiment is not limited thereto.

In the present embodiment, the memory 1150 stores the following elements of an operating system 1151 and an application program 1152, including an executable module and a data structure, a subset of the operating system 1151 and the application program 1152 or an extended set of the operating system 1151 and the application program 1152.

Specifically, the operating system 1151 includes a variety of system programs including a framework layer, a core library layer and a driver layer, which are used to implement various basic services and process hardware-based tasks. The application program 1152 includes a variety of application programs including a Media Player and a Browser, which are used to implement various application services. Programs of implementing the method of the embodiments of the present disclosure may be included in the application program 1152. The application program 1152 includes applets, objects, components, logic, data structures, and other computer-executable instructions that perform specific tasks or implement specific abstract data types.

In addition, the present embodiment also provides a computer-readable storage medium in which a computer program is stored. The computer-readable storage medium may be non-transitory. The computer program is executed by a processor, such that respective steps of the method of designing the metasurface are implemented and the same technical effect is achieved. Further details will not be discussed herein for the purpose of avoiding repetition.

The computer-readable storage medium includes a medium that is permanent, non-permanent, removable or non-removable. The media is a tangible device being capable of reserving and storing instructions which are usable to an instruction execution device. The computer-readable storage medium may be an electronic storage device, a magnetic storage device, an optical storage device, an electromagnetic storage device, a semiconductor storage device, or a combination thereof. The computer-readable storage medium includes a phase-change random access memory (PRAM), a static random access memory (SRAM), a dynamic random access memory (DRAM), other types of random access memory (RAM), a read only memory (ROM), a Non-volatile random access memory (NVRAM), an electrically erasable programmable read-only memory (EEPROM), a flash memory or other memory techniques, a compact disc read-only memory (CD-ROM), a digital versatile disc (DVD) or other optical storage devices, a magnetic cassette storage device, a tape disk storage device or other magnetic storage devices, a memory stick, a mechanical encoding device (such as punched cards or raised structures in grooves in which instructions are recorded) or any other Non-transmission media, which are used to store information that is accessible by a computing device. According to the definition in the present embodiment, the computer-readable storage medium does not include a transient signal itself. The transient signal may be, for example, radio waves or other freely propagating electromagnetic waves, electromagnetic waves propagating through waveguides or other transmission media (such as light pulses passing through fiber optic cables) or an electrical signal transmitted through a wire.

It should be understood that the device, the equipment and the method provided in the embodiments of the present disclosure may be implemented in other ways. For example, the devices described above are only illustrative. Taking the modules or the units as an example, the division of modules or the units is performed according to logical functions. In actual implementation, there may be other division methods, for example, multiple units or multiple components may be combined or integrated into another system. Or, some features are ignored, or are not implemented. In addition, indirect coupling or direct coupling or communication connection as shown or as discussed may be realized by some interfaces, devices or units, or may be realized through electrical connection, mechanical connection, or connection in other forms.

The units described as separate components may or may not be physically separated. The components in the form of units may be or may not be physical units, which may be located at one location or may be distributed to multiple network units. Some or all of the units may be selected according to actual needs to solve problems in the embodiments of the present disclosure.

In addition, respective functional units in the embodiments of the present disclosure may be integrated into one processing unit, or may be physical existences that are independent, or two or more units may be integrated into one unit. The integrated unit may be implemented in the form of hardware or software functional units.

The integrated unit may be stored in a computer-readable storage medium when the integrated unit is implemented in the form of software functional units, and is sold or used as an independent product. Based on this understanding, core parts of technical solutions or parts of the technical solutions that contribute to the prior art, or all or a part of the technical solutions of the embodiments of the present disclosure may be embodied in the form of a computer software product. The computer software product is stored in a storage medium and the computer software product includes a plurality of instructions. The plurality of instructions are configured to cause a computer device to execute all or a part of steps of the method described in the embodiments of the present disclosure, where the computer device may be a personal computer, a server, a data center or other network devices. The storage medium may be any of aforementioned mediums being capable of storing program code.

According to descriptions of the embodiments of the present disclosure, those skilled in the art should know that the embodiments of the present disclosure may be implemented in the form of the method, the device, the equipment and the storage media. Therefore, the embodiments of the present disclosure may be implemented in the following forms: complete hardware, complete software, or a combination of hardware and software. Where, the complete software may be a firmware, a resident software or a microcode. Furthermore, in some embodiments, the present disclosure may also be implemented in the form of a computer program product in one or more computer-readable storage mediums, where, the one or more computer-readable storage mediums contain computer program code.

The above-mentioned computer-readable storage medium may be any combination of one or more computer-readable storage mediums. The computer-readable storage medium includes electrical, magnetic, optical, electromagnetic, infrared or semiconductor systems, devices or equipment, or any combination thereof. More specifically, the computer-readable storage medium may be a portable computer disk, a hard disk, a random access memory (RAM), a read-only memory (ROM), an erasable and programmable read-only memory (EPROM), a flash memory, an optical fiber, a compact disk read-only memory (CD-ROM), an optical storage device, a magnetic storage device, or any combination thereof. In the embodiments of the present disclosure, a computer-readable storage medium may be any tangible medium in which a program is contained or stored. The program may be used by an instruction execution system, an instruction execution device, an instruction execution equipment or a combination thereof.

The computer program code included in the computer-readable storage medium may be transmitted by any appropriate medium, including wireless, wire, optical cables, radio frequency (RF), or any combination thereof.

Computer program code for performing steps of the embodiments of the present disclosure may be written in assembly instructions, instruction set architecture (ISA) instructions, machine instructions, machine-related instructions, microcode, firmware instructions, state setting data, integrated circuit configuration data, or in one or more programming languages or a combination thereof. The programming languages include object-oriented programming languages, such as Java, Smalltalk, and C++. The programming languages also include conventional procedural programming languages, such as C language or similar programming languages. The computer program code may execute on the user's computer entirely or partly, or may execute as a stand-alone software package, or may execute partially on the user's computer and partially on the remote computer, or may execute entirely on a remote computer or a remote server. In the case that the remote computer is involved, the remote computer may be connected to the user's computer or to an external computer over any kind of network, such as a local area network (LAN) and a wide area network (WAN).

In the embodiments of the present disclosure, the method, the device and the equipment are described through flow charts and/or block diagrams.

It should be understood that each block or any combination of the blocks in the flow charts and/or the block diagrams may be implemented by computer-readable program instructions. These computer-readable program instructions may be provided to a processor of a general-purpose computer, a special-purpose computer, or other programmable data processing apparatuses to produce a machine. The computer-readable program instructions may be executed by the computer or other programmable data processing apparatuses to produce a device which implements functions or operations specified by the blocks in the flow charts and/or the block diagrams.

The computer-readable program instructions may also be stored in a computer-readable storage medium that enables a computer or other programmable data processing apparatuses to operate in a specific way. Such that, the computer-readable program instructions stored in the computer-readable storage medium produce a device including instructions to implement the functions or the operations specified by the blocks in the flow charts and/or the block diagrams.

Computer-readable program instructions may also be loaded onto a computer, other programmable data processing apparatuses, or other devices, so that a series of operation steps are executed by the computer, the other programmable data processing apparatuses, or the other devices, thereby producing a computer-implementable process. Thus, the instructions are executed on the computer or on the other programmable data processing apparatuses, which enable the implementation of functions or operations specified by the blocks in the flow charts and/or the block diagrams.

The embodiments of the present disclosure mentioned above are illustrative, and are not intended to limit the present disclosure. The scope of the embodiments of the present disclosure is not limited thereto. All variations or substitutions that are easily thought of by those skilled in the art fall within the scope of the present disclosure. Accordingly, the scope of the present application is defined by the appended claims.

What is claimed is:

1. A method of designing a metasurface, comprising:
determining a type of an incident beam and parameters of the incident beam; wherein the parameters of the incident beam comprise a wavelength of the incident beam and a light intensity distribution of the incident beam;
determining a type of an outgoing beam and a parameter of the outgoing beam; wherein the parameter of the outgoing beam comprises a light intensity distribution of the outgoing beam;
based on the parameters of the incident beam and the parameter of the outgoing beam, determining an initial value of a diffraction phase distribution; the diffraction phase distribution represents a phase distribution configured to modulate the incident beam to the outgoing beam; and
based on the type of the incident beam and the type of the outgoing beam, iteratively optimizing the diffraction phase distribution to obtain an optimized diffraction phase distribution; generating a target phase distribution according to the optimized diffraction phase distribution; and generating the metasurface according to the target phase distribution.

2. The method of designing the metasurface according to claim 1, wherein a step of determining the initial value of the diffraction phase distribution based on the parameters of the incident beam and the parameter of the outgoing beam comprises:
determining a two-dimensional phase distribution; wherein the two-dimensional phase distribution represents a phase distribution configured to modulate the incident beam directed towards the metasurface which is of a plane defined by a first direction and a second direction; the first direction represents a direction that is coplanar with the metasurface to be designed; and the first direction and the second direction are perpendicular to each other; and
taking the two-dimensional phase distribution as the initial value of the diffraction phase distribution.

3. The method of designing the metasurface according to claim 2, wherein a step of determining the two-dimensional phase distribution comprises:
redistributing the light intensity distribution of the incident beam into the light intensity distribution of the outgoing beam to obtain a one-dimensional phase distribution; the one-dimensional phase distribution represents a phase distribution that modulates the incident beam directed in the first direction; and
determining the two-dimensional phase distribution according to a type of the light intensity distribution of the outgoing beam and the one-dimensional phase distribution.

4. The method of designing the metasurface according to claim 3, wherein the incident beam is a Gaussian beam; and the outgoing beam is a flat-top beam.

5. The method of designing the metasurface according to claim 3, wherein the type of the light intensity distribution of the outgoing beam is of a rotationally symmetrical shape.

6. The method of designing the metasurface according to claim 5, wherein the type of the light intensity distribution of the outgoing beam is of a cylinder; and a step of determining the two-dimensional phase distribution according to the type of the light intensity distribution of the outgoing beam and the one-dimensional phase distribution comprises:
performing a rotational symmetry to the one-dimensional phase distribution to obtain the two-dimensional phase distribution.

7. The method of designing the metasurface according to claim 3, wherein the type of the light intensity distribution of the outgoing beam is out of a rotationally symmetrical shape.

8. The method of designing the metasurface according to claim 7, wherein the type of the light intensity distribution of the outgoing beam is of a cuboid; and a step of determining the two-dimensional phase distribution according to the type of the light intensity distribution of the outgoing beam and the one-dimensional phase distribution comprises:
determining a phase distribution configured to modulate the incident beam directed in the second direction; superimposing the phase distribution configured to modulate the incident beam directed in the second direction and the one-dimensional phase distribution to obtain the two-dimensional phase distribution.

9. The method of designing the metasurface according to claim 6, wherein the one-dimensional phase distribution satisfies:
$${φ}_{1} ( x ) = \frac{2 π}{λ z} {\int }_{0}^{x} [ u ( t ) - t ] dt ;$$
the two-dimensional phase distribution satisfies:
$${φ}_{2} ( x , y ) = {φ}_{1} ( \sqrt{{x}^{2} + {y}^{2}} ) ;$$
wherein, φ₁(x) represents the one-dimensional phase distribution; x represents a position on the metasurface in the first direction; λ represents the wavelength of the incident beam; z represents a distance that the outgoing beam travels to a diffraction plane; u(t) represents a conversion relationship between a position u of the light intensity distribution of the outgoing beam and a position t of the incident beam in the first direction, and t represents an integral variable; φ₂(x, y) represents the two-dimensional phase distribution; y represents a position on the metasurface in the second direction.

10. The method of designing the metasurface according to claim 8, wherein the two-dimensional phase distribution satisfies:
$${φ}_{2} ( x , y ) = {φ}_{1 x} ( x ) + {φ}_{1 y} ( y ) ;$$
and
$${φ}_{1 x} ( x ) = \frac{2 π}{λ z} {\int }_{0}^{x} [ {u}_{x} ( t ) - t ] dt ; {φ}_{1 y} ( y ) = \frac{2 π}{λ z} {\int }_{0}^{y} [ {u}_{y} ( t ) - t ] dt ;$$
wherein, φ₂(x, y) represents the two-dimensional phase distribution; λ represents the wavelength of the incident beam; z represents a distance that the outgoing beam travels to a diffraction plane; t represents an integral variable; φ₁ₓ(x) represents a one-dimensional phase distribution in the first direction; x represents a position on the metasurface in the first direction; uₓ(t) represents a conversion relationship between a position uₓ of the light intensity distribution of the outgoing beam in the first direction x and a position t of the incident beam in the first direction x; φ_{1y}(y) represents a one-dimensional phase distribution in the second direction; y represents a position on the metasurface in the second direction; u_{y}(t) represents a conversion relationship between a position u_{y} of the light intensity distribution of the outgoing beam in the second direction y and a position t of the incident beam in the second direction y.

11. The method of designing the metasurface according to claim 1, wherein a step of iteratively optimizing the diffraction phase distribution based on the type of the incident beam and the type of the outgoing beam to obtain the optimized diffraction phase distribution comprises:
determining a first light source function of the incident beam according to the type of the incident beam; and determining a second light source function of the outgoing beam according to the type of the outgoing beam; and
plugging the initial value of the diffraction phase distribution into a phase recovery algorithm, and performing an optimization based on the first light source function and the second light source function to obtain the optimized diffraction phase distribution.

12. The method of designing the metasurface according to claim 1, wherein a step of generating the target phase distribution according to the optimized diffraction phase distribution comprises:
taking the optimized diffraction phase distribution as the target phase distribution.

13. The method of designing the metasurface according to claim 1, wherein a step of generating the target phase distribution according to the optimized diffraction phase distribution comprises:
superimposing an additional phase distribution on the optimized diffraction phase distribution to obtain the target phase distribution; wherein the additional phase distribution represents a phase distribution configured for collimating the incident beam or configured for focusing the outgoing beam.

14. The method of designing the metasurface according to claim 13, wherein the additional phase distribution satisfies:
$${φ}_{3} ( x , y ) = - \frac{2 π}{λ} ( \sqrt{{x}^{2} + {y}^{2} + {f}^{2}} - f ) ;$$
wherein, φ₃(x, y) represents an additional phase distribution of the metasurface to be designed at a position (x, y); A represents the wavelength of the incident beam; f represents a focal length of the metasurface to be designed.

15. A beam shaper, comprising: a metasurface designed by the method of designing the metasurface according to claim 1.

16. A device of designing a metasurface, comprising: a first determination module, a second determination module, a generation module and an optimization module;
wherein the first determination module is configured to determine a type of an incident beam and parameters of the incident beam; the parameters of the incident beam comprise a wavelength of the incident beam and a light intensity distribution of the incident beam;
the second determination module is configured to determine a type of an outgoing beam and a parameter of the outgoing beam; the parameter of the outgoing beam comprises a light intensity distribution of the outgoing beam;
the generation module is configured to determine an initial value of a diffraction phase distribution based on the parameters of the incident beam and the parameter of the outgoing beam; the diffraction phase distribution represents a phase distribution configured to modulate the incident beam to the outgoing beam; and
the optimization module is configured to iteratively optimize the diffraction phase distribution based on the type of the incident beam and the type of the outgoing beam to obtain an optimized diffraction phase distribution; and the optimization module is also configured to generate a target phase distribution according to the optimized diffraction phase distribution and generate the metasurface according to the target phase distribution.

17. Electronic equipment, comprising: a processor and a memory, the memory comprises a computer program stored in the memory,
wherein the processor is configured to execute the computer program stored in the memory, so as to implement the method of designing the metasurface of claim 1.

18. A non-transitory computer-readable storage medium in which a computer program is stored, wherein the computer program is executed by a processor, so as to implement the method of designing the metasurface of claim 1.
